(19) United States
(12) Patent Application Publication
(10) Pub. No.: US 2026/0260669 A1
(43) Pub. Date: Sep. 3, 2026

(54) SEMICONDUCTOR STRUCTURES IN MEMORY DEVICES

(71) Applicant: Yangtze Memory Technologies Co., Ltd., Wuhan (CN)

(72) Inventors: Zishan HUANG, Wuhan (CN); Danyang LI, Wuhan (CN); Yu WANG, Wuhan (CN)

(21) Appl. No.: 19/175,699

(22) Filed: Apr. 10, 2025

Related U.S. Application Data
(63) Continuation of application No. PCT/CN2025/080256, filed on Mar. 3, 2025.

(51) Int. Cl. G11C 5/02; G11C 5/06; G11C 11/408; G11C 11/4091; G11C 11/4093; H10B 12/00

(52) U.S. Cl. CPC G11C 5/025; G11C 5/063; G11C 11/4085; G11C 11/4091; G11C 11/4093; H10B 12/50

(57) ABSTRACT

Memory devices having semiconductor structures and memory systems are provided. In one aspect, a memory device includes a first semiconductor structure, and a second semiconductor structure stacked with the first semiconductor structure. The first semiconductor structure has a memory array including a plurality of memory banks. The second semiconductor structure includes a control circuitry. The control circuitry includes a plurality of bank circuits corresponding to the plurality of memory banks, and a peripheral circuit arranged to one side of the plurality of bank circuits. The peripheral circuit includes a first regulator coupled to bit lines in a first memory bank of the plurality of memory banks. A first bank circuit corresponding to the first memory bank includes a second regulator coupled to the bit lines in the first memory bank.

### CROSS-REFERENCE TO RELATED APPLICATIONS

This application is a continuation of International Application No. PCT/CN2025/080256, filed on Mar. 3, 2025, the disclosure of which is hereby incorporated by reference in its entirety.

### TECHNICAL FIELD

The present disclosure relates to semiconductor devices, e.g., memory devices.

### BACKGROUND

Semiconductor devices, e.g., memory devices, can have various structures to increase the density of memory cells and lines on a chip. A memory device normally includes a memory array of memory cells and a control circuitry for facilitating operations of the memory array.

### SUMMARY

The present disclosure describes managing semiconductor structures in memory devices.

One aspect of the present disclosure features a memory device. The memory device includes a memory array including a plurality of memory banks. The memory device further includes a control circuity. The control circuitry includes a first regulator coupled to bit lines in a first memory bank of the plurality of memory banks. The control circuitry further includes a second regulator coupled to the bit lines in the first memory bank. An output of the first regulator is coupled to an output of the second regulator.

In some implementations, the second regulator is closer to the first memory bank than the first regulator.

In some implementations, the control circuitry further includes a third regulator coupled to bit lines in a second memory bank of the plurality of memory banks. Bit lines in the second memory bank are further coupled to the first regulator. An output of the third regulator is coupled to the output of the first regulator.

In some implementations, the control circuitry includes a plurality of bank circuits corresponding to the plurality of memory banks. The control circuitry further includes a peripheral circuit arranged to one side of the plurality of bank circuits. The second regulator is included in a first bank circuit corresponding to the first memory bank, and the first regulator is included in the peripheral circuit.

In some implementations, each of the plurality of bank circuits comprises a corresponding second regulator coupled to bit lines in a corresponding memory bank of the plurality of memory banks.

In some implementations, the first bank circuit further includes one or more sense amplifiers coupled to the bit lines in the first memory bank, and one or more word line drivers coupled to word lines in the first memory bank. The peripheral circuit includes an input/output circuit of the memory device.

In some implementations, the second regulator is on an edge of the first bank circuit.

In some implementations, a first output of the first regulator is coupled to a first output of the second regulator in the first bank circuit. A second output of the first regulator is coupled to a second output of the second regulator in the first bank circuit.

In some implementations, the bit lines in the first memory bank are numbered in sequence. The first output of the first regulator and the first output of the second regulator are coupled to odd-numbered bit lines of the bit lines in the first memory bank. The second output of the first regulator and the second output of the second regulator are coupled to even-numbered bit lines of the bit lines in the first memory bank.

In some implementations, the first regulator includes one or more first operational amplifiers, one or more first transistors and one or more capacitors. The second regulator includes one or more second operational amplifiers and one or more second transistors.

In some implementations, transistors included in the one or more second operational amplifiers are smaller in size than transistors included in the one or more first operational amplifiers.

In some implementations, the first regulator is configured to operate while the first memory bank is in an inactive mode and while the first memory bank is in an active mode. The second regulator is configured to operate while the first memory bank is in the active mode, and to be disabled while the first memory bank is in the inactive mode.

In some implementations, the second regulator is configured to be disabled by an internal switch in a corresponding second operational amplifier in the second regulator.

Another aspect of the present disclosure features a memory device. The memory device includes a first semiconductor structure, and a second semiconductor structure stacked with the first semiconductor structure. The first semiconductor structure has a memory array including a plurality of memory banks. The second semiconductor structure includes a control circuitry. The control circuitry includes a plurality of bank circuits corresponding to the plurality of memory banks, and a peripheral circuit arranged to one side of the plurality of bank circuits. The peripheral circuit includes a first regulator coupled to bit lines in a first memory bank of the plurality of memory banks. A first bank circuit corresponding to the first memory bank includes a second regulator coupled to the bit lines in the first memory bank.

In some implementations, the first semiconductor structure includes first contact structures isolated by a first isolating material, and the second semiconductor structure comprises second contact structures isolated by a second isolating material. The first semiconductor structure and the second semiconductor structure are bonded together by the first contact structures being in contact with the second contact structures.

In some implementations, the plurality of bank circuits are arranged in two rows. An output of the first regulator is coupled to outputs of second regulators in bank circuits in a first row. The peripheral circuit further includes an additional first regulator, where an output of the additional first regulator is coupled to outputs of second regulators in bank circuits in a second row.

In some implementations, the control circuitry includes a plurality of bank circuits corresponding to the plurality of memory banks. The control circuitry further includes a peripheral circuit arranged to one side of the plurality of bank circuits. The second regulator is included in a first bank circuit corresponding to the first memory bank, and the first regulator is included in the peripheral circuit.

In some implementations, each of the plurality of bank circuits includes a corresponding second regulator coupled to bit lines in a corresponding memory bank of the plurality of memory banks.

In some implementations, the second regulator is on an edge of the first bank circuit.

A further aspect of the present disclosure features a memory system. The memory system includes a memory device and a memory controller coupled to the memory device and configured to control the memory device. The memory device includes a memory array including a plurality of memory banks. The memory device further includes a control circuity. The control circuitry includes a first regulator coupled to bit lines in a first memory bank of the plurality of memory banks, and a second regulator coupled to the bit lines in the first memory bank. An output of the first regulator is coupled to an output of the second regulator.

The details of one or more implementations of the subject matter of this present disclosure are set forth in the accompanying drawings and the description below. Other features, aspects, and advantages of the subject matter will become apparent from the description, the drawings, and the claims.

### BRIEF DESCRIPTION OF THE DRAWINGS

The accompanying drawings, which are incorporated herein and form a part of the present disclosure, illustrate aspects of the present disclosure and, together with the description, further serve to explain the principles of the present disclosure and to enable a person of ordinary skill in the pertinent art to make and use the present disclosure.

FIG. 1 illustrates a schematic diagram of an example memory device including a control circuitry and an array of memory cells each having a vertical transistor.

FIG. 2 illustrates an example memory device having a memory array and an example control circuitry.

FIG. 3 illustrates a layout view of an example control circuitry.

FIG. 4 illustrates an example memory device, where the memory array and the control circuitry are formed on the same wafer.

FIG. 5A illustrates a schematic view of a cross-section of an example memory device, where the memory array and the control circuitry are formed on different wafers.

FIG. 5B illustrates a schematic view of a cross-section of another example memory device, where the memory array and the control circuitry are formed on different wafers.

FIG. 6 illustrates an example control circuitry including a global bit-line regulator.

FIG. 7 illustrates another example control circuitry including a global bit-line regulator and local bit-line regulators.

FIG. 8 illustrates example connections among bank circuits, local bit-line regulators, and global bit-line regulators.

FIG. 9 illustrates a schematic view of an example local bit-line regulator.

FIG. 10 illustrates a schematic view of an example global bit-line regulator.

FIG. 11 illustrates a schematic view of an example sense amplifier.

FIG. 12 illustrates performances of a memory device having local bit-line regulators and a memory device without local bit-line regulators.

FIG. 13 illustrates a block diagram of an example system having one or more memory devices.

Like reference numbers and designations in the various drawings indicate like elements. It is also to be understood that the various exemplary implementations shown in the figures are merely illustrative representations and are not necessarily drawn to scale.

### DETAILED DESCRIPTION

A Dynamic Random Access Memory (DRAM) device can include a memory array and a control circuitry coupled to the memory array. In some implementations, the memory array is formed on a first semiconductor structure (e.g., a first wafer) and the control circuitry is formed on a second semiconductor structure (e.g., a second wafer). The first semiconductor structure and the second semiconductor structure can be bonded together to form the memory device.

The control circuitry can include a plurality of bank circuits that each correspond to (e.g., control) a respective memory bank of the memory array. The control circuitry can further include a peripheral circuit arranged to one side of the bank circuits. The peripheral circuit can include circuits configured to control more than one memory bank.

The control circuitry can include bit-line regulators configured to provide a bias voltage to bit lines in the memory banks. In some cases, the bit-line regulators are placed in the peripheral circuit and configured to provide the bias voltage for bit lines in more than one memory bank. The bit-line regulators in the peripheral circuit are referred to as global bit-line regulators in the present disclosure. The routing between the global bit-lines regulators and the bit lines may be long. As such, when the global bit-line regulators provide the bias voltage for the bit lines, the transient response can be slow. There may also be a large voltage drop due to the continuous large current in the routing.

The present disclosure provides techniques to improve voltage supply to bit lines in a memory device. In some implementations, in addition to the global bit-line regulators in the peripheral circuit, the control circuitry can include a bit-line regulator in each bank circuit. The bit-line regulator in a bank circuit can be referred to as a local bit-line regulator in the present disclosure. A local bit-line regulator can be configured to provide the bias voltage to bit lines in the memory bank corresponding to the bank circuit comprising the local bit-line regulator. In some implementations, the local bit-line regulator can be enabled or disabled by the corresponding bank control logic. For example, the local bit-line regulator can be enabled when the corresponding memory bank is in an active mode (e.g., when data is read from or written to the memory bank), and can be disabled when the corresponding memory bank is in an inactive mode.

Implementations of the present disclosure can provide one or more of the following technical benefits and/or advantages. For example, by including the local bit-line regulators, the routing between the bit-line regulators and the bit lines can be shortened. The transient response can be improved, and the bias voltage provided for the bit lines can be more stable. As an example, during operations such as a refresh operation where there is a continuous large current in the routing between the bit-line regulators and the bit lines, there can be a smaller variation in the bias voltage provided for the bit lines. In addition, local bit-line regulators can be accommodated in spare areas of the control circuitry. Implementations of the present disclosure can be achieved in a cost-effective manner without increasing die size. In some implementations, different or additional technical advantages may be achieved.

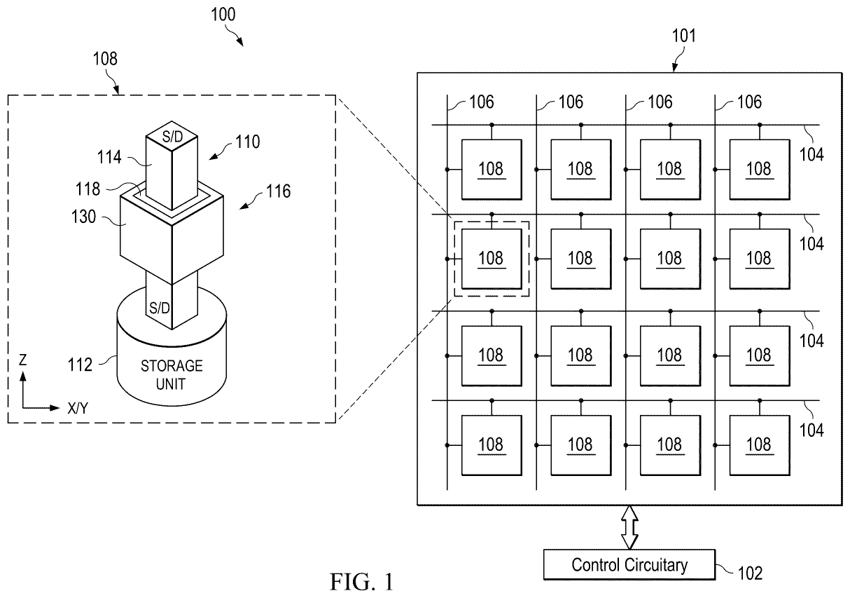

FIG. 1 illustrates a schematic diagram of a memory device 100 including a control circuitry and an array of memory cells each having a vertical transistor, according to some aspects of the present disclosure. The memory device 100 can include a memory array 101 and a control circuity 102 coupled to the memory array 101. The memory array 101 can be any suitable memory cell array in which each memory cell 108 includes a vertical transistor 110 and a storage unit 112 coupled to the vertical transistor 110. In some implementations, the memory array 101 is a DRAM cell array, and the storage unit 112 is a capacitor for storing charge as the binary information stored by the respective DRAM cell. In some implementations, the memory array 101 is a PCM cell array, and storage unit 112 is a PCM element (e.g., including chalcogenide alloys) for storing binary information of the respective PCM cell based on the different resistivities of the PCM element in the amorphous phase and the crystalline phase. In some implementations, the memory array 101 is a FRAM cell array, and the storage unit 112 is a ferroelectric capacitor for storing binary information of the respective FRAM cell based on the switch between two polarization states of ferroelectric materials under an external electric field.

As shown in FIG. 1, memory cells 108 can be arranged in a two-dimensional (2D) array having rows and columns. The memory device 100 can include word lines 104 coupling the control circuitry 102 and memory array 101 for controlling the switch of vertical transistors 110 in memory cells 108 located in a row. The memory device 100 can include bit lines 106 coupling control circuitry 102 and memory array 101 for sending data to and/or receiving data from memory cells 108 located in a column. That is, each word line 104 is coupled to a respective row of memory cells 108 in the memory array 101, and each bit line is coupled to a respective column of memory cells 108 (e.g., a string of memory cells 108) in the memory array 101.

In some implementations, a memory cell 108 can include a vertical transistor 110, such as a vertical metal-oxide-semiconductor field-effect transistor (MOSFET), instead of a planar transistor as a pass transistor, to reduce the area occupied by the pass transistors of the memory cells 108, reduce the coupling capacitance, as well as reduce the interconnect routing complexity. As shown in FIG. 1, in some implementations, different from planar transistors in which the active regions are formed in the substrates, vertical transistor 110 includes a semiconductor body 114 extending vertically (in the z direction) above the substrate (not shown). That is, the semiconductor body 114 can extend above the top surface of the substrate to expose not only the top surface of the semiconductor body 114, but also one or more side surfaces thereof. As shown in FIG. 1, for example, the semiconductor body 114 can have a cuboid shape to expose four sides thereof. It is understood that the semiconductor body 114 may have any suitable 3D shape, such as polyhedron shapes or a cylinder shape. That is, the cross-section of the semiconductor body 114 in the plan view (e.g., in the x-y plane) can have a square shape, a rectangular shape (or a trapezoidal shape), a circular (or an oval shape), or any other suitable shapes.

As shown in FIG. 1, the vertical transistor 110 can also include a gate structure 116 in contact with one or more sides of the semiconductor body 114, e.g., in one or more planes of the side surface(s) of the active region. In other words, the active region of vertical transistor 110, e.g., semiconductor body 114, can be at least partially surrounded by the gate structure 116. The gate structure 116 can include a gate dielectric 118 over one or more sides of semiconductor body 114, e.g., in contact with four side surfaces of semiconductor body 114 as shown in FIG. 1. The gate structure 116 can also include a gate electrode 120 over and in contact with gate dielectric 118. Gate dielectric 118 can include any suitable dielectric materials, such as silicon oxide, silicon nitride, silicon oxynitride, or high-k dielectrics. For example, gate dielectric 118 may include gate oxide (e.g., silicon oxide). Gate electrode 120 can include any suitable conductive materials, such as polysilicon, metals (e.g., tungsten (W), copper (Cu), aluminum (Al), etc.), metal compounds (e.g., titanium nitride (TiN), tantalum nitride (TaN), etc.), or silicides. For example, gate electrode 120 may include doped polysilicon, i.e., a gate poly. In some implementations, gate electrode 120 includes multiple conductive layers, such as a W layer over a TiN layer. It is understood that gate electrode 120 and word line 104 may be a continuous conductive structure in some examples. In other words, gate electrode 120 may be viewed as part of word line 104 that forms gate structure 116, or word line 104 may be viewed as the extension of gate electrode 120 to be coupled to the control circuitry 102.

As shown in FIG. 1, vertical transistor 110 can further include a pair of a source and a drain (a.k.a., source electrode and drain electrode) formed at the two ends of semiconductor body 114 in the vertical direction (z-direction), respectively. The source and drain can be doped with any suitable P-type dopants, such as boron (B) or Gallium (Ga), or any suitable N-type dopants, such as phosphorus (P) or arsenic (As). The source and drain can be separated by gate structure 116 in the vertical direction (z-direction). In other words, gate structure 116 is formed vertically between the source and drain. As a result, one or more channels (not shown) of vertical transistor 110 can be formed in the semiconductor body 114 vertically between the source and drain when a gate voltage applied to gate electrode 120 of gate structure 116 is above the threshold voltage of vertical transistor 110. That is, each channel of vertical transistors 110 is also formed in the vertical direction along which semiconductor body 114 extends, according to some implementations.

In some implementations, as shown in FIG. 1, vertical transistor 110 is a multi-gate transistor. That is, gate structure 116 can be in contact with more than one side of semiconductor body 114 (e.g., four sides in FIG. 1) to form more than one gate, such that more than one channel can be formed between the source and drain in operation. That is, different from the planar transistor that includes only a single planar gate (and resulting in a single planar channel), vertical transistor 110 shown in FIG. 1 can include multiple vertical gates on multiple sides of semiconductor body 114 due to the 3D structure of semiconductor body 114 and gate structure 116 that surrounds the multiple sides of semiconductor body 114. As a result, compared with planar transistors, vertical transistor 110 shown in FIG. 1 can have a larger gate control area to achieve better channel control with a smaller subthreshold swing. During the off state, since the channel is fully depleted, the leakage current of vertical transistor 110 can be significantly reduced as well. The multi-gate vertical transistors can include double-gate vertical transistors (e.g., dual-side gate vertical transistors), tri-gate vertical transistors (e.g., tri-side gate vertical transistors), and GAA vertical transistors.

It is understood that although vertical transistor 110 is shown as a multi-gate transistor in FIG. 1, the vertical transistors disclosed herein may also include single-gate transistors as described below in detail. That is, gate structure 116 may be in contact with a single side of semiconductor body 114, for example, for the purpose of increasing the transistor and memory cell density. It is also understood that although gate dielectric 118 is shown as being separate (e.g., as a separate structure) from other gate dielectrics of adjacent vertical transistors (not shown), gate dielectric 118 may be part of a continuous dielectric layer having multiple gate dielectrics of vertical transistors.

In planar transistors and some lateral multiple-gate transistors (e.g., FinFET), the active regions, such as semiconductor bodies (e.g., Fins), extend laterally (in the x-y plane), and the source and the drain are disposed at different locations in the same lateral plane (the x-y plane). In contrast, in vertical transistor 110, semiconductor body 114 extends vertically (in z-direction), and the source and the drain are disposed in the different lateral planes, according to some implementations. In some implementations, the source and the drain are formed at two ends of semiconductor body 114 in the vertical direction (the z direction), respectively, thereby being overlapped in the plan view. As a result, the area (in the x-y plane) occupied by vertical transistor 110 can be reduced compared with planar transistor and lateral multiple-gate transistors. Also, the metal wiring coupled to vertical transistors 110 can be simplified since the interconnects can be routed in different planes. For example, bit lines 106 and storage units 112 may be formed on opposite sides of vertical transistor 110. In one example, bit line 106 may be coupled to the source or the drain at the upper end of semiconductor body 114, while storage unit 112 may be coupled to the other source or the drain at the lower end of semiconductor body 114.

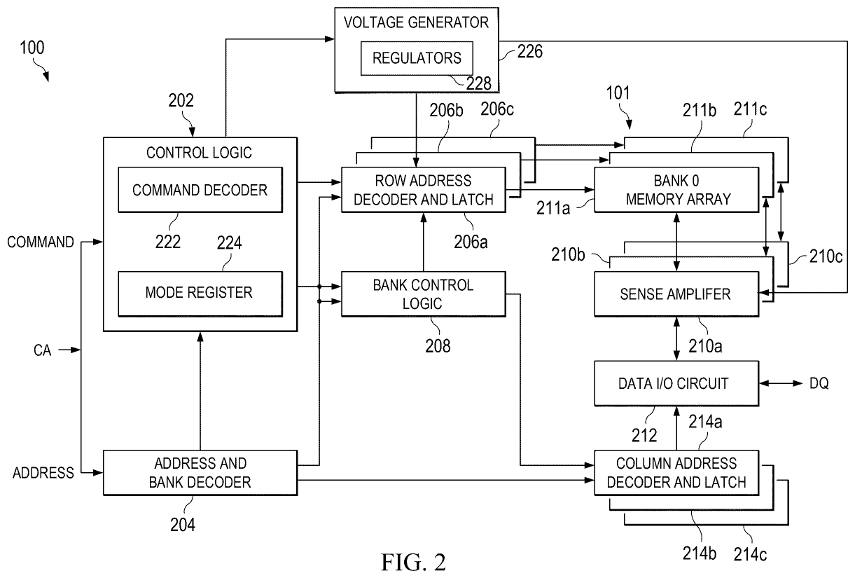

FIG. 2 illustrates an example memory device 100 having a memory array 101 and an example control circuitry 102, according to some aspects of the present disclosure. The control circuitry 102 can be coupled to the memory array 101 through bit lines 106 and word lines 104. The control circuitry 102 can include any suitable analog, digital, and mixed-signal circuits for facilitating the operations of the memory array 101. The control circuitry 102 can include various types of circuits formed using metal-oxide-semiconductor (MOS) technologies. The example control circuitry 102 includes control logic 202, address and bank decoder 204, row address decoder and latch 206, bank control logic 208, sense amplifier 210, data input/output (I/O) circuit 212, a column address decoder and latch 214, and a voltage generator 226. In some examples, additional circuits not shown in FIG. 2 may be included in the control circuitry 102 as well.

In some implementations, the memory array 101 can include a number of memory banks 211. Each memory bank 211 can include memory cells 108 arranged in rows and in columns. Memory banks 211 can be accessed and operated independently from one another. As an example in FIG. 2, the memory array 101 includes memory banks 211a, 211b, 211c (collectively as 211). In other examples, the memory array 101 can include any suitable number of memory banks 211. For instance, a memory array 101 can include memory banks 211 arranged in two rows, where each row has 8 memory banks 211. In some implementations, each memory bank 211a, 211b, 211c can be controlled by a corresponding row address decoder and latch 208a, 208b, 208c (collectively as 208), a corresponding sense amplifier 210a, 210b, 210c (collectively as 210), and a corresponding column address decoder and latch 214a, 214b, 214c (collectively as 214).

The control logic 202 can be configured to control operations of other circuits of the control circuitry 102. The control logic 202 can include a command decoder 222 configured to decode commands received by the memory device 100 (e.g., from a memory controller coupled to the memory device 100), and generate instructions to be sent to other circuits such as bank control logic 208 and the row address decoder and latch 206. The control logic can also include a number of registers, such as mode registers 224 that store information such of configuration parameters, circuit status, pre-set data pattern, etc. Different mode registers 224, or different sets of mode registers 224, may be designated for different uses.

The address and bank decoder 204 can be configured to decode address signals received by the memory device 100. The address and bank decoder 204 can send row addresses, column addresses, and signals indicating selected memory banks 211 (e.g., decoded from the address signals) to the row address decoder and latch 206, the column address decoder and latch 214, and the bank control logic 208, respectively.

The row address decoder and latch 206 can be configured to decode the row address received from the address and bank decoder 204, and enable a word line 104 connected to a row of memory cells 108 for data to be written to or to be read from, according to the decoded row address.

The column address decoder and latch 214 can be configured to decode the column address received from the address and bank decoder 204, and enable a bit line 106 connected to a column of memory cells 108 for data to be written to or to be read from, according to the decoded column address.

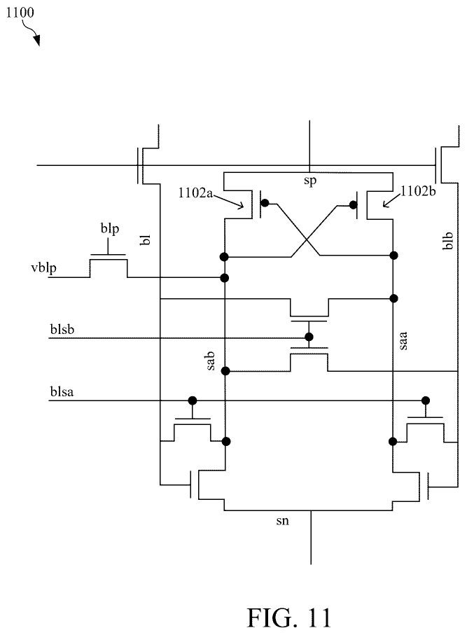

The sense amplifier 210 can sense and amplify data of a memory cell and can store data in the memory cell. The sense amplifier 210 can be implemented by a cross-coupled amplifier connected between a bit line and a complementary bit line, which are included in the memory array 101. A schematic view of an example sense amplifier is discussed in greater details below with reference to FIG. 11.

The bank control logic 208 can be configured to control operations on selected memory banks 211, for example, by controlling a row address decoder and latch 206a, 206b, 206c, a column address decoder and latch 214a, 214b, 214c, and/or a sense amplifier 210a, 210b, 210c that corresponds to a selected memory bank 211a, 211b, 211c.

The data I/O circuit 212 can write input data to the memory array 101, and can read output data from the memory array 101. The data I/O circuit 212 can include a read latch to temporality hold data to be sent to the memory controller, and a write latch to temporality hold data received from the memory controller. In some implementations, the data input/output circuit 212 can include data masking logic configured to select certain portions of data, for example, by masking invalid data bits and keeping valid data bits in a read or a write operation.

The voltage generator 226 can be configured to be controlled by the control logic 202 and generate word line voltages (e.g., read voltage, program voltage, pass voltage, verify voltage, etc.), bit line voltages, to be supplied to the memory array 101. The voltage generator 226 can include regulators 228, including word-line regulators configured to provide power for word lines 104 to activate or deactivate memory cells 108 coupled to the word lines 104 during read and write operations. The regulators 228 can also include bit-line regulators configured to provide power for bit lines 106 during data sensing. In some implementations, bit lines 106 in one memory bank 211 are coupled to at least one bit-line regulator, which can provide a bias voltage (e.g., at half of the supply voltage) to the bit lines 106 via the sense amplifier 210. The bit-line regulator can charge the bit lines to the bias voltage during a precharging phase, and the bias voltage can be used as a reference voltage during a sensing phase that follows the precharging phase. For example, during the sensing phase, the sense amplifier 210 can amplify the small voltage difference between a bit line 106 and the reference voltage to determine whether the stored data in a memory cell 108 coupled to the bit line 106 is a logical “1” or a “0”. As such, data can be read from the memory cells.

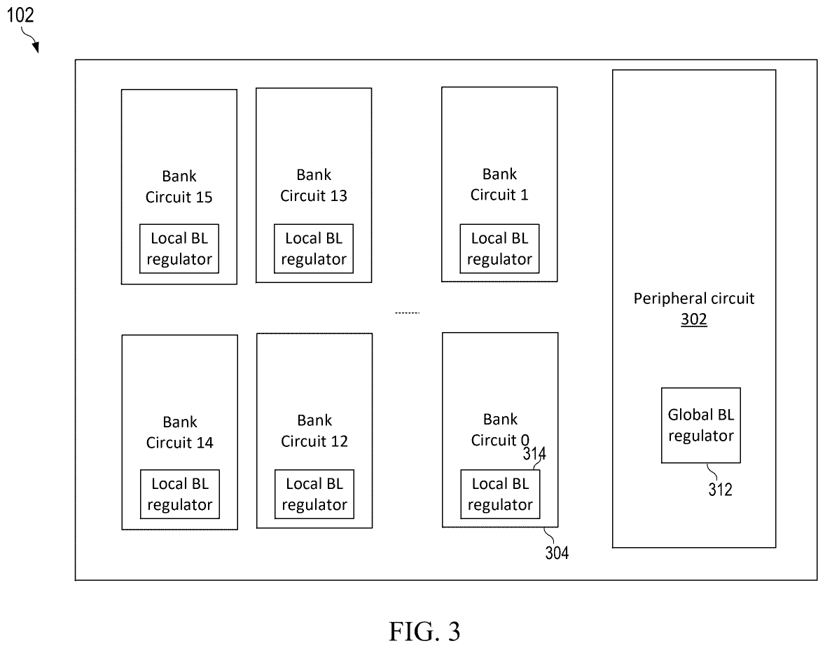

FIG. 3 illustrates a layout view of an example control circuitry 102. The control circuitry 102 can include a peripheral circuit 302 and bank circuits 304.

Each of the bank circuits 304 can be coupled to a specific memory bank (e.g., memory bank 211 of FIG. 2) of the memory array. In some implementations, a bank circuit 304 can include circuits that are configured to control a specific memory bank. For example, bank circuit 0 can include a row address decoder and latch 206a, a word line driver, a column address decoder and latch 214a and a sense amplifier 210a that are coupled to the corresponding memory bank 211a; bank circuit 1 can include a row address decoder and latch 208b, a word line driver, a column address decoder and latch 214b and a sense amplifier 210b that are coupled to the corresponding memory bank 211b; and so on.

The peripheral circuit 302 can include circuits that are configured to control more than one memory bank. For example, the peripheral circuit 302 can include control logic 202, address and bank decoder 204, and data I/O circuit 212.

In some implementations, the peripheral circuit 302 can include one or more global bit-line regulators 312. Further, in some implementations, each bank circuit 304 can include a local bit-line regulator 314. A global bit-line regulator 312 is coupled to bit lines in more than one memory banks, via the sense amplifier of the respective bank circuit 304. For example, the peripheral circuit 302 can include one global bit-line regulator 312, which is coupled to and configured to provide power for bit lines in all memory banks of the memory array. For another example, the peripheral circuit 302 can include two global bit-line regulators 312, where each global bit-line regulator 312 is coupled to and configured to provide power for bit lines in one row of memory banks of the memory array. A local bit-line regulator 314 is coupled to and configured to provide power for bit lines in a specific memory bank, that is, the memory bank corresponding to the bank circuit 304 that includes the local bit-line regulator 314.

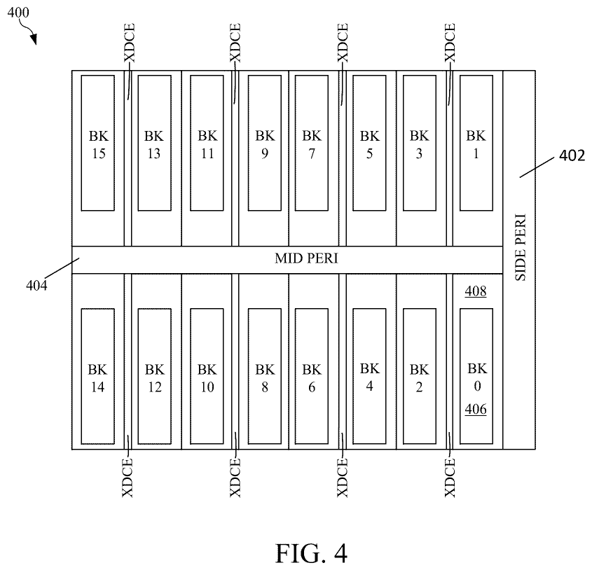

In some implementations, as shown in FIG. 3, the peripheral circuit 302 is arranged to one side of the bank circuits. In some other implementations, as shown in FIG. 4, the peripheral circuit 302 can include a side peripheral circuit 402 arranged to one side of the bank circuits 304, and a middle peripheral circuit 404 arranged between two rows of bank circuits 304.

FIG. 4 illustrates an example memory device 400 (e.g., memory device 100 of FIGS. 1-2), where the memory array (e.g., the memory array 101 of FIG. 1) and the control circuitry (e.g., the control circuitry 102 of FIG. 1) are formed on the same wafer. As an example, the memory array of the memory device 400 includes 16 memory banks 406 (BANK 0 to 15) arranged in two rows. The memory bank 211 of FIG. 2 can an example of the memory bank 406. The control circuitry of the memory device 400 can include 16 bank circuits 408 (e.g., bank circuit 304 of FIG. 3) and a peripheral circuit (e.g., the peripheral circuit 302 of FIG. 3). The peripheral circuit can include a side peripheral circuit 402 arranged to one side of the bank circuits 408, and a middle peripheral circuit 404 arranged between the two rows of bank circuits 408.

As shown in FIG. 4, the memory array and the control circuitry of the memory device 400 can be formed on the same wafer. The memory bank 406 coupled to and controlled by each bank circuit 408 (e.g., bank circuit 304 of FIG. 3) can be integrally formed and arranged in the same area as the bank circuit 408. As an example, bank circuits 408 can be formed surrounding respective memory banks 406.

In some implementations, a row address decoder (e.g., row address decoder and latch 206 of FIG. 2) can be shared and arranged between two adjacent bank circuits 408. As an example shown in FIG. 4, the bank circuit coupled to BANK 0 and the bank circuit coupled to BANK 2 share the row address decoder arranged between the two bank circuits; the bank circuit coupled to BANK 1 and the bank circuit coupled to BANK 3 share the row address decoder arranged between the two bank circuits; and so on.

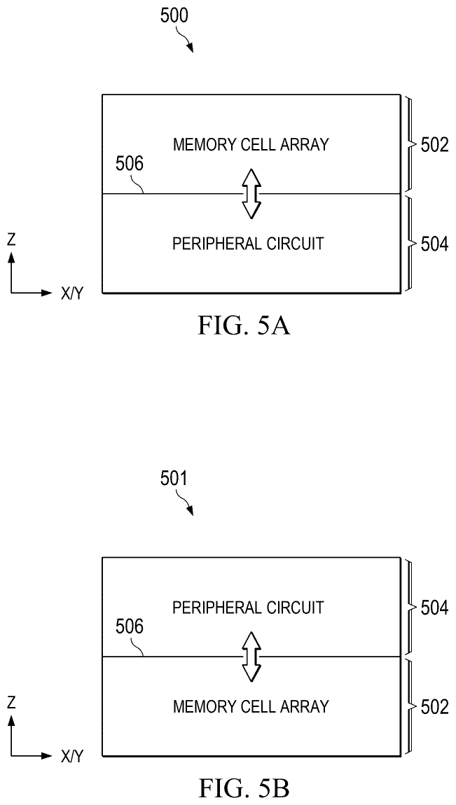

FIG. 5A illustrates a schematic view of a cross-section of an example memory device 500, where the memory array and the control circuitry are formed on different wafers. The memory device 100 of FIGS. 1-2 can be an example of the memory device 500.

The memory device 500 represents an example of a bonded chip. The components of t he memory device 500 (e.g., memory array and control circuitry) can be formed separately on different wafers and then joined to form a bonded chip. The memory device 500 can include a first semiconductor structure 502 including the memory array (e.g., the memory array 101 of FIGS. 1-2). The memory device 500 can also include a second semiconductor structure 504 including the control circuitry (e.g., the control circuitry 102 of FIGS. 1-3). The control circuitry can include any suitable digital, analog, and/or mixed-signal circuits used for facilitating the operations of the memory array. For example, the control circuitry can include one or more of a decoder (e.g., a row decoder and a column decoder), a sense amplifier, a driver (e.g., a word line driver), an input/output (I/O) circuit, a charge pump, a voltage source or generator, a current or voltage reference, any portions (e.g., a subcircuit) of the functional circuits mentioned above, or any active or passive components of the circuit (e.g., transistors, diodes, resistors, or capacitors). The control circuitry in the second semiconductor structure 504 use complementary metal-oxide-semiconductor (CMOS) technology, which can be implemented, for example, with logic processes (e.g., technology nodes of 90 nm, 65 nm, 60 nm, 45 nm, 32 nm, 28 nm, 22 nm, 20 nm, 16 nm, 14 nm, 10 nm, 7 nm, 5 nm, 3 nm, 2 nm, etc.), according to some implementations.

As shown in FIG. 5A, the memory device 500 can also include the first semiconductor structure 502 including an array of memory cells (memory array) that can use transistors as the switch and selecting devices. In some implementations, the memory array includes an array of DRAM cells. For ease of description, a DRAM cell array may be used as an example for describing the memory array in the present disclosure. But it is understood that the memory array is not limited to DRAM cell array and may include any other suitable types of memory arrays that can use transistors as the switch and selecting devices, such as PCM cell array, static random-access memory (SRAM) cell array, FRAM cell array, resistive memory array, magnetic memory array, spin transfer torque (STT) memory array, to name a few, or any combination thereof.

As shown in FIG. 5A, the memory device 500 further includes a bonding interface 506 vertically between (in the vertical direction, e.g., the z-direction in FIG. 5A) the first semiconductor structure 502 and the second semiconductor structure 504. As described below in detail, the first and second semiconductor structures 502 and 504 can be fabricated separately (and in parallel in some implementations), such that the thermal budget of fabricating one of the first and second semiconductor structures 502 and 504 does not limit the processes of fabricating another one of the first and second semiconductor structures 502 and 504.

Moreover, a large number of interconnects (e.g., contact structures) can be formed through the bonding interface 506 to make direct, short-distance (e.g., micron-level) electrical connections between first semiconductor structure 502 and second semiconductor structure 504, as opposed to the long-distance (e.g., millimeter or centimeter-level) chip-to-chip data bus on the circuit board, such as printed circuit board (PCB), thereby eliminating chip interface delay and achieving high-speed I/O throughput with reduced power consumption. Data transfer between the memory array in first semiconductor structure 502 and the control circuitry in second semiconductor structure 504 can be performed through the interconnects (e.g., contact structures) across the bonding interface 506. For example, the first semiconductor structure 502 can include first contact structures (e.g., made of a conductive material such as W and/or TiN) isolated by a first isolating material (e.g., silicon oxide), and the second semiconductor structure 504 can include second contact structures (e.g., made of a conductive material such as W and/or TiN) isolated by a second isolating material (e.g., silicon oxide). The first semiconductor structure 502 and the second semiconductor structure 504 can be bonded together by the first contact structures being in contact with the second contact structures. By vertically integrating the first and second semiconductor structures 502 and 504, the chip size can be reduced, and the memory cell density can be increased.

In some implementations, when the first semiconductor structure 502 and the second semiconductor structure 504 are stacked and bonded together, each memory bank of the memory array in the first semiconductor structure 502 overlaps, or partially overlaps, with a corresponding bank circuit (e.g., bank circuit 304 of FIG. 3) of the control circuitry in the x-y plane. As such, high-speed data transmission can be achieved between the memory array included in the first semiconductor structure 502 and the control circuitry included in the second semiconductor structure 504.

It is understood that the relative positions of stacked first and second semiconductor structures 502 and 504 are not limited. FIG. 5B illustrates a schematic view of a cross-section of another example memory device 501. Different from the memory device 500 in FIG. 5A in which the first semiconductor structure 502 including the memory array is above the second semiconductor structure 504 including the control circuitry, in the memory device 501 in FIG. 5B, the second semiconductor structure 504 including the peripheral circuit is above the first semiconductor structure 502 including the memory array. Nevertheless, the bonding interface 506 is formed vertically between the first and second semiconductor structures 502 and 504 in the memory device 501, and the first and second semiconductor structures 502 and 504 are joined vertically through bonding (e.g., hybrid bonding) according to some implementations. Hybrid bonding, also known as “metal/dielectric hybrid bonding”, is a direct bonding technology (e.g., forming bonding between surfaces without using intermediate layers, such as solder or adhesives) and can obtain metal-metal (e.g., copper-to-copper) bonding and dielectric-dielectric (e.g., silicon oxide-to-silicon oxide) bonding simultaneously. Data transfer between the memory array in the first semiconductor structure 502 and the control circuitry in the second semiconductor structure 504 can be performed through the interconnects (e.g., contact structures) across bonding interface 506.

It is noted that x, y, and z axes are included in FIGS. 5A and 5B to further illustrate the spatial relationship of the components in the memory devices 500 and 501. The substrate of the memory device includes two lateral surfaces extending laterally in the x-y plane: a top surface on the front side of the wafer on which the semiconductor devices can be formed, and a bottom surface on the backside opposite to the front side of the wafer. The z-axis is perpendicular to both the x and y axes. As used herein, whether one component (e.g., a layer or a device) is “on,” “above,” or “below” another component (e.g., a layer or a device) of the memory device is determined relative to the substrate of the memory device in the z-direction (the vertical direction perpendicular to the x-y plane, e.g., the thickness direction of the substrate) when the substrate is positioned in the lowest plane of the memory device in the z-direction. The same notion for describing the spatial relationships is applied throughout the present disclosure.

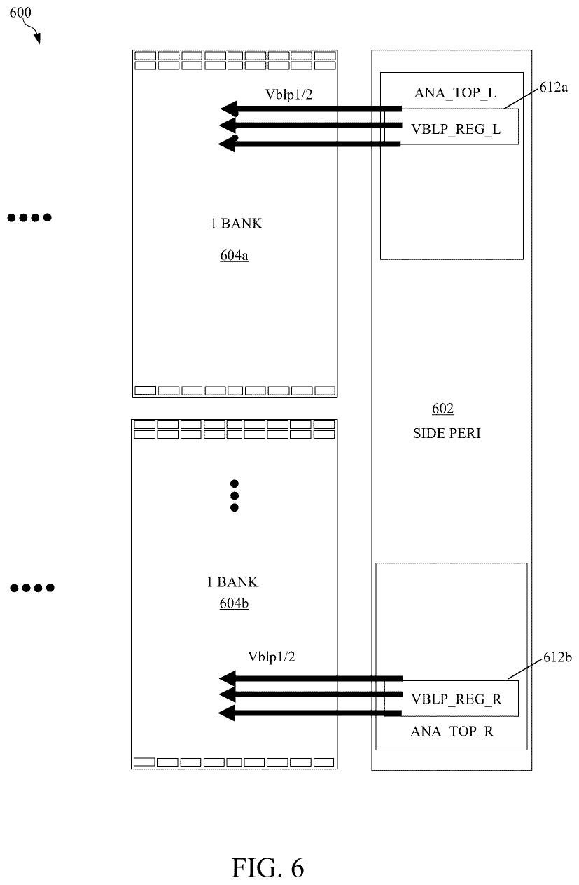

FIG. 6 illustrates an example control circuitry 600 including a global bit-line regulator. The control circuitry 600 includes a plurality of bank circuits 604 (including 604a and 604b) and a peripheral circuit 602 arranged to one side of the plurality of bank circuits 604. The control circuitry 600 includes at least one global bit-line regulator 612 (including 612a and 612b) in the peripheral circuit 602, while the bank circuits 604 do not include bit-line regulators.

As an example, the peripheral circuit 602 can include a global bit-line regulator 612, which is coupled to bits lines in corresponding memory banks, through sense amplifiers (e.g., sense amplifiers 210 of FIG. 2) of respective bank circuits 604. As another example shown in FIG. 6, the control circuitry 600 includes two rows of bank circuits 604. The global bit-line regulator 612a (e.g., arranged in an upper portion of the peripheral circuit 602) is coupled to bit lines in memory banks that correspond to bank circuits 602a in the first row, through respective sense amplifiers of the bank circuits 602a in the first row. The global bit-line regulator 612b (e.g., arranged in a lower portion of the peripheral circuit 602) is coupled to bit lines in memory banks that correspond to bank circuits 602b in the second row, through respective sense amplifiers of the bank circuits 602a in the second row. It should be noted that the bank circuits 604 can be arranged in any suitable number of rows, each row can include any suitable number of bank circuit 604, and that the peripheral circuit 602 can include any suitable number of global bit-line regulators 612.

In some cases, since some bank circuits (e.g., Bank Circuits 14 and 15 of FIG. 3) are further away from the peripheral circuit 602 than other bank circuits (e.g., Bank Circuits 0 and 1 of FIG. 3), the metal routing between sense amplifiers in these bank circuits (e.g., Bank Circuits 14 and 15 of FIG. 3) and the global bit-line regulator 612 may be longer. As such, there may be a delayed transient response and a large voltage drop when providing power for bit lines in memory banks (e.g., BANKS 14 and 15 of FIG. 4) that correspond to these bank circuits.

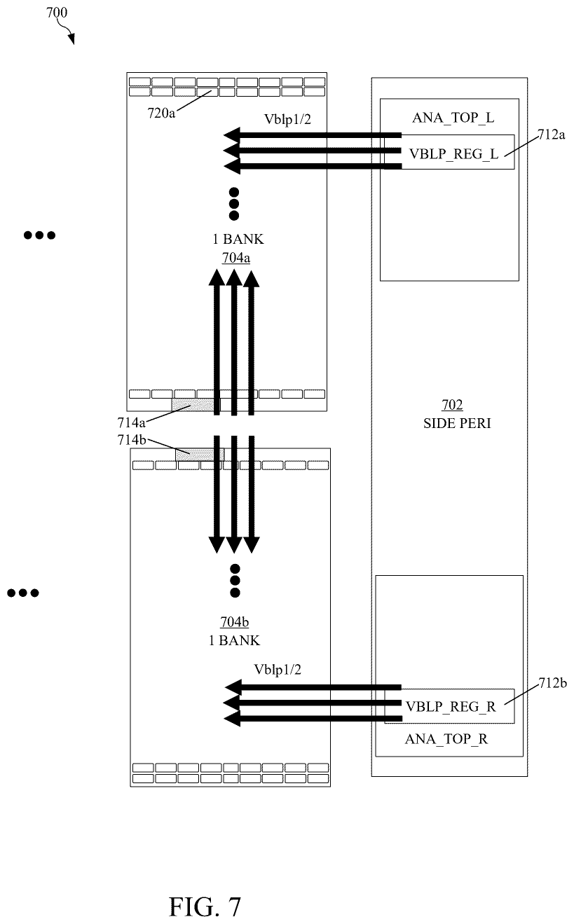

FIG. 7 illustrates an example control circuitry 700 including a global bit-line regulator and local bit-lines regulators. The control circuitry 700 includes a plurality of bank circuits 704 (including 704a and 704b) and a peripheral circuit 702 arranged to one side of the plurality of bank circuits 704. Apart from one or more global bit-line regulators 712 (including 712a and 712b) in the peripheral circuit 702, the control circuitry 700 also includes local bit-line regulators 714 (including 714a and 714b) in the bank circuits 704. The global bit-line regulators 712 and the local bit-line regulators 714 can form a power mesh, where bit lines in each memory bank are powered by both a global bit-line regulator 712 in the peripheral circuit 702 and a local bit-line regulator 714 in the corresponding bank circuit 704.

As shown in FIG. 7, both the global bit-line regulator 712a (e.g., in an upper portion of the peripheral circuit 702) and the local bit-line regulator 714a in the bank circuit 704a are coupled to and configured to provide power for bit lines in the memory bank corresponding to the bank circuit 704a. In some implementations, the output of the global bit-line regulator 712a and the output of the local bit-line regulator 714a are coupled together, and then further coupled to the sense amplifier in the bank circuit 704a to provide power for the bit lines through the sense amplifier.

In some implementations, the global bit-line regulator 712a is configured to provide power for bit lines in more than one memory bank. For example, the global bit-line regulator 712a can be configured to provide power for bits lines in memory banks corresponding to all bank circuits (e.g., Bank Circuit 1, . . . , 13 and 15 of FIG. 3) in the first row. The output of the global bit-line regulator 712a is coupled to the output of each local bit-line regulator in the bank circuits in the first row, and further coupled to bit lines in the memory banks corresponding to bank circuits in the first row. The global bit-line regulator 712a is configured to operate all the time, regardless of whether the memory bank corresponding to the bank circuit 704a is in an active mode or in an inactive mode. The local bit-line regulator 714a is configured to provide power for bit lines in a specific memory bank, that is, the memory bank corresponding to the bank circuit 704a. As such, the local bit-line regulator 714a can be configured to operate while the memory bank is in the active mode, and be disabled while the memory bank is in the inactive mode.

Similarly, both the global bit-line regulator 712b (e.g., in a lower portion of the peripheral circuit 702) and the local bit-line regulator 714b in the bank circuit 704b are coupled to and configured to provide power for bit lines in the memory bank corresponding to the bank circuit 704b. In some implementations, the output of the global bit-line regulator 712b and the output of the local bit-line regulator 714b are coupled together, and then further coupled to the sense amplifier in the bank circuit 704b to provide power for the bit lines through the sense amplifier.

In some implementations, the global bit-line regulator 712b is configured to provide power for bit lines in more than one memory bank. For example, the global bit-line regulator 712b can be configured to provide power for bits lines in memory banks corresponding to all bank circuits (e.g., Bank Circuit 0, . . . , 12 and 14 of FIG. 3) in the second row. The output of the global bit-line regulator 712b is coupled to the output of each local bit-line regulator in the bank circuits 704 in the second row, and further coupled to bit lines in the memory banks corresponding to bank circuits 704 in the second row. The global bit-line regulator 712b is configured to operate all the time, regardless of whether the memory bank corresponding to the bank circuit 704b is in an active mode (e.g., when data are written to or read from the memory bank) or in an inactive mode. The local bit-line regulator 714b is configured to provide power for bit lines in a specific memory bank, that is, the memory bank corresponding to the bank circuit 704b. As such, the local bit-line regulator 714b can be configured to operate while the memory bank is in the active mode, and be disabled while the memory bank is in the inactive mode.

In some implementations, a local bit-line regulator 714 can be arranged on an edge of the respective bank circuit 704. For example, the local bit-line regulator 714a can be arranged to one side (e.g., to the left, to the right of, on top of, or below) of all the block circuits 720a (e.g., circuits configured to control specific memory blocks of the memory bank) of the bank circuit 704a.

As shown in FIG. 7, local bit-line regulators 714 are closer to respective sense amplifiers than the global bit-line regulators 712. As such, the power mesh that includes both local bit-line regulators 714 and global bit-line regulators 712 can improve transient response and reduce the voltage drop when providing power to bit lines, so that the bias voltage provided to the bit lines can be more stable.

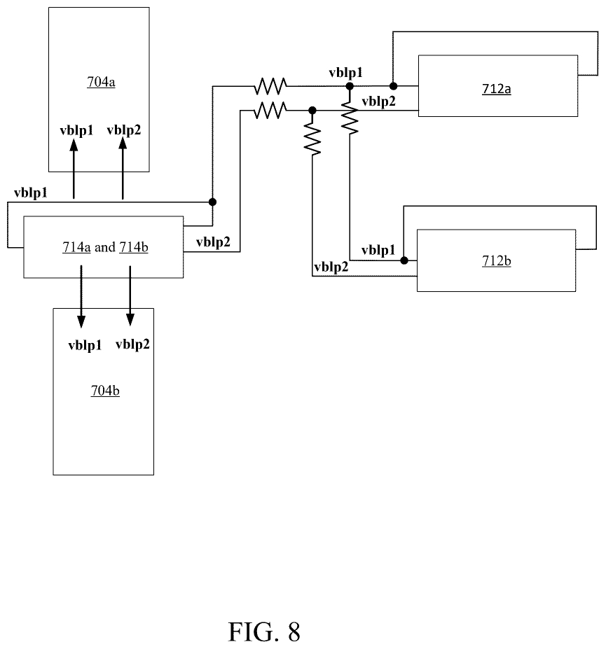

FIG. 8 illustrates example connections among bank circuits 704, local bit-line regulators 714, and global bit-line regulators 712.

Each global bit-line regulator 712 (including 712a and 712b) has a first output (vblp1) and a second output (vblp2). Each local bit-line regulator 714 (including 714a and 714b) has a first output (vblp1) and a second output (vblp2). In some implementations, the first output of all the bit-line regulators 712, 714 are coupled together and output the same voltage, and the second output of all the bit-line regulators 712, 714 are coupled together and output the same voltage. For example, as shown in FIG. 8, the first output of the global bit-line regulator 712a is coupled to the first output of the local bit-line regulator 714a; the second output of the global bit-line regulator 712a is coupled to the second output of the local bit-line regulator 714a; the first output of the global bit-line regulator 712b is coupled to the first output of the local bit-line regulator 714b; and the second output of the global bit-line regulator 712b is coupled to the second output of the local bit-line regulator 714b.

Further, the first output of a local bit-line regulator 714 can be coupled to an input of the local bit-line regulator 714 to provide a feedback signal. The first output of a global bit-line regulator 712 can be coupled to an input of the global bit-line regulator 712 to provide a feedback signal.

In some implementations, the voltages from the first output (vblp1) and the second output (vblp2) have the same voltage value but opposite voltage phases. Further, bit lines in a memory bank can be numbered in sequence (e.g., from 0 to n). The first output (vblp1) of the global bit-line regulator 712 and the first output (vblp1) of the local bit-line regulator 714 can be coupled to odd-numbered bit lines in the memory bank, for example, through sense amplifiers coupled to the odd-numbered bit lines. The second output (vblp2) of the global bit-line regulator 712 and the second output (vblp2) of the local bit-line regulator 714 can be coupled to even-numbered bit lines in the memory bank, for example, through sense amplifiers coupled to the even-numbered bit lines.

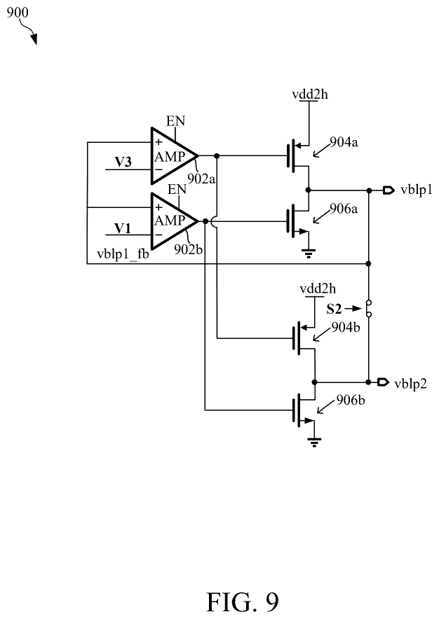

FIG. 9 illustrates a schematic view of an example local bit-line regulator 900. The local bit-line regulator 900 can be an example of the local bit-line regulator 314 of FIG. 3 and local bit-line regulator 714 of FIG. 7. The local bit-line regulator 900 can include one or more operational amplifiers 902 (including 902a and 902b).

As shown in FIG. 9, the operational amplifier 902a receives a voltage (v3) as its first input, and receives the first output (vblp1) as its second input. The output of the operational amplifier 902a is coupled to the gate of one or more transistors 904a and 904b (e.g., P-MOS transistors). The operational amplifier 902b receives a voltage (v1) as its first input, and receives the first output (vblp1) as its second input. The output of the operational amplifier 902b is coupled to the gate of one or more transistors 906a and 906b (e.g., N-MOS transistors). A transistor pair comprising the transistor 904a and the transistor 906a is coupled between a power source voltage (vdd2h) and a ground voltage, and can output the first output (vblp1). A transistor pair comprising the transistor 904b and the transistor 906b is coupled between the power source voltage (vdd2h) and the ground voltage, can output the second output (vblp2).

In some implementations, each operational amplifier 902 can include an enable pin as an internal switch. The enable pin can receive a control signal indicating whether to enable or disable the operational amplifier 902. For example, the operational amplifier 902 can be disabled when the memory bank corresponding to the bank circuit comprising the local bit-line regulator 900 is in an inactive mode, so that the local bit-line regulator 900 can be disabled.

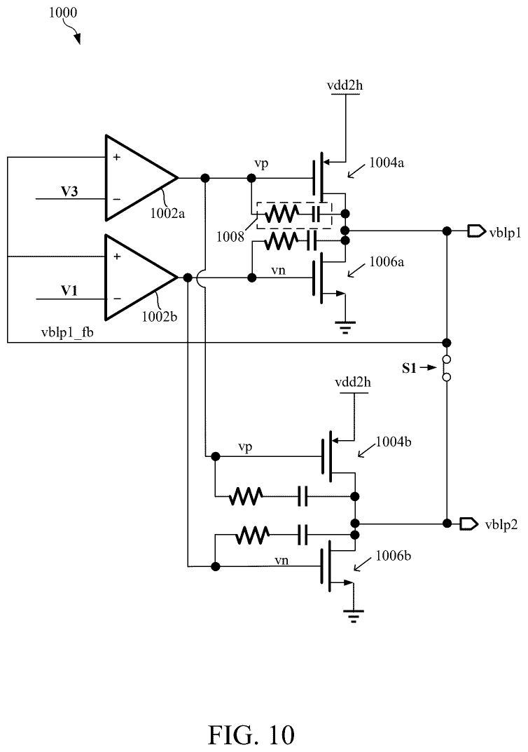

FIG. 10 illustrates a schematic view of an example global bit-line regulator 1000. The global bit-line regulator 1000 can be an example of the global bit-line regulator 312 of FIG. 3, and global bit-line regulator 712 of FIG. 7.

Similar to the local bit-line regulator 900, the global bit-line regulator 1000 includes one or more operational amplifiers 1002 (including 1002a and 1002b). The operational amplifier 1002a receives a voltage (v3) as its first input, and receives the first output (vblp1) as its second input. The output of the operational amplifier 1002a is coupled to the gate of one or more transistors 1004a and 1004b (e.g., P-MOS transistors). The operational amplifier 1002b receives a voltage (v1) as its first input, and receives the first output (vblp1) as its second input. The output of the operational amplifier 1002b is coupled to the gate of one or more transistors 1006a and 1006b (e.g., N-MOS transistors). A transistor pair comprising the transistor 1004a and the transistor 1006a is coupled between a power source voltage (vdd2h) and a ground voltage, can output the first output (vblp1). A transistor pair comprising the transistor 1004b and the transistor 1006b is coupled between the power source voltage (vdd2h) and the ground voltage, can output the second output (vblp2).

In some implementations, different from the local bit-line regulator 900, the global bit-line regulator 1000 can further include one or more capacitor-inductor pairs 1008. For example, the global bit-line regulator 1000 can include a capacitor-inductor pair 1008 between an output of each operational amplifier 1002 and the first/second output (vblp1 or vblp2). By having the capacitor-inductor pairs 1008, the global bit-line regulator 1000 can stabilize voltage during transient load changes, for example, by reducing oscillation. In comparison, by not having the capacitor-inductor pairs, the response of the local bit-line regulator 900 can be faster, e.g., by directly responding to changes without needing to charge or discharge the capacitor-inductor pairs.

In some implementations, the transistors in the local bit-line regulator 900 (including transistors 904, 906, and/or transistors comprised in the operational amplifiers 902) can be smaller in size than the transistors in the global bit-line regulators 1000 (including transistors 1004, 1006, and/or transistors comprised in the operations amplifiers 1002. As such, the local bit-line regulator 900 may take up a smaller area on the wafer than the global bit-line regulator 1000, so that the local bit-line regulator 900 may be easily accommodated in the bank circuit.

FIG. 11 illustrates a schematic view of an example sense amplifier 1100. The sense amplifier 210 can include a plurality of sense amplifiers 1100, where each sense amplifier 1100 can be coupled to a bit line (e.g., bit line 106 of FIG. 1) in a memory bank.

As shown in FIG. 11, the sense amplifier 1100 can include a cross-coupled amplifier between a bit line (bl) and a complementary bit line (blb). The cross-coupled amplifier can include two transistors 1102a, 1102b (e.g., P-MOS transistors). In some implementations, the cross-coupled amplifier can include two N-MOS transistors. The cross-coupled amplifier can be controlled by two power source signals (sp/sn), which can drive bit line voltages to a higher voltage or a lower voltage.

For example, during a pre-charging phase, the bit line (bl) and the complementary bit line (blb) can both be precharged to a bias voltage, with the output (vblp) of the bit-line regulators 900 or 1000 as the precharge power supply. During a sensing phase, the voltage of the bit line (bl) may change due to the small amount of charge from the memory cell connecting to the bit line, while the voltage of the complementary bit line (blb) remains at the bias voltage. The cross-coupled amplifier can amplify the small voltage difference between the bit line (bl) and the complementary bit line (blb), so that data (e.g., logic “0” or logic “1”) can be read from the memory cell.

In some implementations, additional control signals (e.g., “sab” and “saa”) can enable specific read and write functionalities of the sense amplifier during memory operations, ensuring proper data flow to and from the memory array.

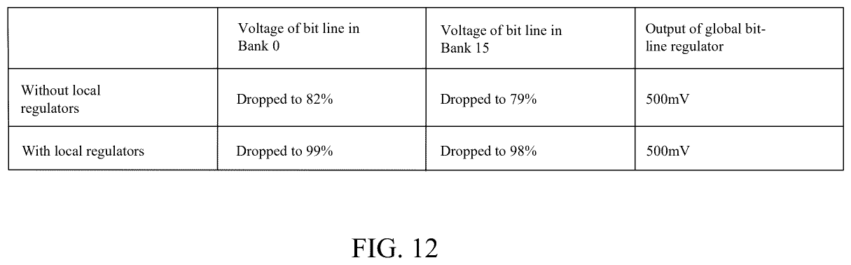

FIG. 12 illustrates performances of a memory device having local bit-line regulators and a memory device without local bit-line regulators.

As shown in FIG. 12, in a memory device having a control circuitry (e.g., control circuitry 600 of FIG. 6) that has global bit-line regulators but does not have local bit-line regulators, due to the long wiring between the global bit-line regulators and the bit lines, there may a large voltage drop from the bit-line regulators to the bit lines. For example, with reference to FIG. 3, under the scenario where the output voltage (vblp) of the bit-line regulator is around 500 mV, the voltage of bit lines in memory bank 0 (e.g., the memory bank that corresponds to Bank Circuit 0, which is closer to the global bit-line regulators) may be powered to 82% of the output voltage (vblp), with a 18% voltage drop. The voltage of the bit lines in memory bank 15 (e.g., the memory bank that corresponds to Bank Circuit 15, which is farther from the global bit-line regulators) may be powered to 79% of the output voltage (vblp), with more than 20% voltage drop.

In comparison, in a memory device having a control circuitry (e.g., control circuitry 700 of FIG. 7) that has both global bit-line regulators and local bit-line regulators, bit lines in memory banks can response to whichever bit-line regulator that is closer to the memory bank. Therefore, the voltage drop from the bit-line regulators to the bit lines can be reduced. For example, with reference to FIG. 3, under the scenario where the output voltage (vblp) of the bit-line regulator is around 500 mV, the voltage of bit lines in memory bank 0 (e.g., the memory bank that corresponds to Bank Circuit 0, which is closer to the global bit-line regulators) may be powered to 99% of the output voltage (vblp). The voltage of the bit lines in memory bank 15 (e.g., the memory bank that corresponds to Bank Circuit 15, which is farther from the global bit-line regulators) may be powered to 98% of the output voltage (vblp), with only 2% or less voltage drop.

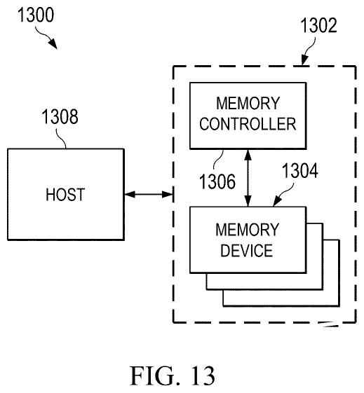

FIG. 13 illustrates a block diagram of a system 1300 having one or more memory devices, according to one or more implementations of the present disclosure. The system 1300 can be a mobile phone, a desktop computer, a laptop computer, a tablet, a server, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 13, the system 1300 can include a host device 1308 and a memory system 1302 having one or more memory devices 1304 and a memory controller 1306. Host device 1308 can include a processor of an electronic device, such as a central processing unit (CPU), or a system-on-chip (SoC), such as an application processor (AP). Host device 1308 can be configured to send or receive data to or from the one or more memory devices 1304.

A memory device 1304 can be any memory device disclosed herein, such as memory device depicted in any one of FIGS. 1-12. In some implementations, a memory device 1304 includes a DRAM memory. Memory controller 1306 (a.k.a., a controller circuit) is coupled to memory device 1304 and host device 1308. Consistent with implementations of the present disclosure, memory device 1304 can include a plurality of conductive interconnections through a cover layer that are in contact with conductive pads in a conductive pad layer, and memory controller 1306 can be coupled to memory device 1304 through at least one of the plurality of conductive interconnections. Memory controller 1306 is configured to control memory device 1304. Memory controller 1306 can manage data stored in memory device 1304 and communicate with host device 1308.

In some implementations, memory controller 1306 is designed/configured for operating in a low duty cycle environment like compact Flash (CF) cards, universal serial bus (USB) Flash drives, or other media for use in electronic devices, such as personal computers, digital cameras, mobile phones, etc. In some implementations, memory controller 1306 is designed/configured for operating in a high duty cycle environment like memory cards, graphic memory, or SSDs used as data storage for mobile devices, such as smartphones, tablets, laptop computers, etc., and enterprise storage arrays. Memory controller 1306 can be configured to control operations of memory device 1304, such as read, program (or write) operations. Memory controller 1306 can also be configured to manage various functions with respect to the data stored or to be stored in memory device 1304 including, but not limited to bad-block management, garbage collection, logical-to-physical address conversion, wear leveling, etc. In some implementations, memory controller 1306 is further configured to process error correction codes (ECCs) with respect to the data read from or written to memory device 1304. Any other suitable functions may be performed by memory controller 1306 as well, for example, formatting memory device 1304.

Memory controller 1306 can communicate with an external device (e.g., host device 1308) according to a particular communication protocol. For example, memory controller 1306 may communicate with the external device through at least one of various interface protocols, such as a USB protocol, a peripheral component interconnection (PCI) protocol, a PCIexpress (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

The present disclosure describes managing semiconductor structures in memory devices. One aspect of the present disclosure features a memory device. The memory device includes a memory array (e.g., memory array 101 of FIGS. 1-3) including a plurality of memory banks (e.g., memory banks 211 of FIG. 2, memory banks 406 of FIG. 4). The memory device further includes a control circuity (e.g., control circuitry 700 of FIG. 7). The control circuitry includes a first regulator (e.g., global bit-line regulator 712a of FIG. 7, global bit-line regulator 1000 of FIG. 10) coupled to bit lines in a first memory bank (e.g., the memory bank corresponding to bank circuit 704a) of the plurality of memory banks. The control circuitry further includes a second regulator (e.g., local bit-line regulator 714a of FIG. 7, local bit-line regulator 900 of FIG. 9) coupled to the bit lines in the first memory bank. An output of the first regulator is coupled to an output of the second regulator.

In some implementations, the second regulator is closer to the first memory bank than the first regulator.

In some implementations, the control circuitry further includes a third regulator (e.g., a local bit-line regulator included in a bank circuit in the same row as the bank circuit 704a of FIG. 7) coupled to bit lines in a second memory bank (e.g., the memory bank corresponding to the bank circuit in the same row as bank circuit 704a of FIG. 7) of the plurality of memory banks. Bit lines in the second memory bank are further coupled to the first regulator. An output of the third regulator is coupled to the output of the first regulator.

In some implementations, the control circuitry includes a plurality of bank circuits (e.g., bank circuits 704 of FIG. 7) corresponding to the plurality of memory banks. The control circuitry further includes a peripheral circuit (e.g., peripheral circuit 702 of FIG. 7) arranged to one side of the plurality of bank circuits. The second regulator is included in a first bank circuit corresponding to the first memory bank, and the first regulator is included in the peripheral circuit.

In some implementations, each of the plurality of bank circuits comprises a corresponding second regulator (e.g., local bit-line regulator) coupled to bit lines in a corresponding memory bank of the plurality of memory banks.

In some implementations, the first bank circuit further includes one or more sense amplifiers (e.g., sense amplifiers 1100 of FIG. 11) coupled to the bit lines in the first memory bank, and one or more word line drivers coupled to word lines in the first memory bank. The peripheral circuit includes an input/output circuit (e.g., data I/O circuit 212 of FIG. 2) of the memory device.

In some implementations, the second regulator is on an edge of the first bank circuit.

In some implementations, a first output (e.g., vblp1) of the first regulator is coupled to a first output (e.g., vblp1) of the second regulator in the first bank circuit. A second output (e.g. vblp2) of the first regulator is coupled to a second output (e.g., vblp2) of the second regulator in the first bank circuit.

In some implementations, the bit lines in the first memory bank are numbered in sequence. The first output of the first regulator and the first output of the second regulator are coupled to odd-numbered bit lines of the bit lines in the first memory bank. The second output of the first regulator and the second output of the second regulator are coupled to even-numbered bit lines of the bit lines in the first memory bank.

In some implementations, the first regulator includes one or more first operational amplifiers, one or more first transistors and one or more capacitors. The second regulator includes one or more second operational amplifiers and one or more second transistors.

In some implementations, transistors included in the one or more second operational amplifiers are smaller in size than transistors included in the one or more first operational amplifiers.

In some implementations, the first regulator is configured to operate while the first memory bank is in an inactive mode and while the first memory bank is in an active mode. The second regulator is configured to operate while the first memory bank is in the active mode, and to be disabled while the first memory bank is in the inactive mode.

In some implementations, the second regulator is configured to be disabled by an internal switch in a corresponding second operational amplifier in the second regulator.

Another aspect of the present disclosure features a memory device. The memory device includes a first semiconductor structure, and a second semiconductor structure stacked with the first semiconductor structure. The first semiconductor structure has a memory array including a plurality of memory banks. The second semiconductor structure includes a control circuitry. The control circuitry includes a plurality of bank circuits corresponding to the plurality of memory banks, and a peripheral circuit arranged to one side of the plurality of bank circuits. The peripheral circuit includes a first regulator coupled to bit lines in a first memory bank of the plurality of memory banks. A first bank circuit corresponding to the first memory bank includes a second regulator coupled to the bit lines in the first memory bank.

In some implementations, the first semiconductor structure includes first contact structures isolated by a first isolating material, and the second semiconductor structure comprises second contact structures isolated by a second isolating material. The first semiconductor structure and the second semiconductor structure are bonded together by the first contact structures being in contact with the second contact structures.

In some implementations, the plurality of bank circuits are arranged in two rows. An output of the first regulator (e.g., the global bit-line regulator 712a of FIG. 7) is coupled to outputs of second regulators in bank circuits in a first row. The peripheral circuit further includes an additional first regulator (e.g., the global bit-line regulator 712b of FIG. 7), wherein an output of the additional first regulator is coupled to outputs of second regulators in bank circuits in a second row.

In some implementations, the control circuitry includes a plurality of bank circuits (e.g., bank circuits 704 of FIG. 7) corresponding to the plurality of memory banks. The control circuitry further includes a peripheral circuit (e.g., peripheral circuit 702 of FIG. 7) arranged to one side of the plurality of bank circuits. The second regulator is included in a first bank circuit corresponding to the first memory bank, and the first regulator is included in the peripheral circuit.

In some implementations, each of the plurality of bank circuits includes a corresponding second regulator coupled to bit lines in a corresponding memory bank of the plurality of memory banks.

In some implementations, the second regulator is on an edge of the first bank circuit.

A further aspect of the present disclosure features a memory system. The memory system includes a memory device and a memory controller coupled to the memory device and configured to control the memory device. The memory device includes a memory array including a plurality of memory banks. The memory device further includes a control circuity. The control circuitry includes a first regulator coupled to bit lines in a first memory bank of the plurality of memory banks, and a second regulator coupled to the bit lines in the first memory bank. An output of the first regulator is coupled to an output of the second regulator.

It is noted that references in the present disclosure to “one embodiment,” “an embodiment,” “an example embodiment,” “some implementations,” “some implementations,” etc., indicate that the embodiment described can include a particular feature, structure, or characteristic, but every embodiment can not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to affect such feature, structure or characteristic in connection with other implementations whether or not explicitly described.

In general, terminology can be understood at least in part from usage in context. For example, the term “one or more” as used herein, depending at least in part upon context, can be used to describe any feature, structure, or characteristic in a singular sense or can be used to describe combinations of features, structures or characteristics in a plural sense. Similarly, terms, such as “a,” “an,” or “the,” again, can be understood to convey a singular usage or to convey a plural usage, depending at least in part upon context. In addition, the term “based on” can be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something, but also includes the meaning of “on” something with an intermediate feature or a layer therebetween. Moreover, “above” or “over” not only means “above” or “over” something, but can also include the meaning it is “above” or “over” something with no intermediate feature or layer therebetween (i.e., directly on something).

Further, spatially relative terms, such as “beneath,” “below,” “lower,” “above,” “upper,” and the like, can be used herein for ease of description to describe one element or feature's relationship to another element(s) or feature(s) as illustrated in the figures. The spatially relative terms are intended to encompass different orientations of the device in use or process step in addition to the orientation depicted in the figures. The apparatus can be otherwise oriented (rotated 90 degrees or at other orientations) and the spatially relative descriptors used herein can likewise be interpreted accordingly.

As used herein, the term “substrate” refers to a material onto which subsequent material layers are added. The substrate includes a “top” surface and a “bottom” surface. The top surface of the substrate is typically where a semiconductor device is formed, and therefore the semiconductor device is formed at a top side of the substrate unless stated otherwise. The bottom surface is opposite to the top surface and therefore a bottom side of the substrate is opposite to the top side of the substrate. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as glass, plastic, or sapphire wafer.

As used herein, the term “layer” refers to a material portion including a region with a thickness. A layer has a top side and a bottom side where the bottom side of the layer is relatively close to the substrate and the top side is relatively away from the substrate. A layer can extend over the entirety of an underlying or overlying structure, or can have an extent less than the extent of an underlying or overlying structure. Further, a layer can be a region of a homogeneous or inhomogeneous continuous structure that has a thickness less than the thickness of the continuous structure. For example, a layer can be located between any set of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductive and contact layers (in which contacts, interconnect lines, and/or vertical interconnect accesses (VIAs) are formed) and one or more dielectric layers.

As used herein, the term “nominal/nominally” refers to a desired, or target, value of a characteristic or parameter for a component or a process step, set during the design phase of a product or a process, together with a range of values above and/or below the desired value. As used herein, the range of values can be due to slight variations in manufacturing processes or tolerances. As used herein, the term “about” indicates the value of a given quantity that can vary based on a particular technology node associated with the subject semiconductor device. Based on the particular technology node, the term “about” can indicate a value of a given quantity that varies within, for example, 10-30% of the value (e.g., ±10%, ±20%, or ±30% of the value).

In the present disclosure, the term “horizontal/horizontally/lateral/laterally” means nominally parallel to a lateral surface of a substrate, and the term “vertical” or “vertically” means nominally perpendicular to the lateral surface of a substrate. The terms “operation” and “step” can be used interchangeably to describe a process.

The present disclosure provides many different implementations, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include implementations in which the first and second features may be in direct contact, and may also include implementations in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various implementations and/or configurations discussed.

The foregoing description of the specific implementations can be readily modified and/or adapted for various applications. Therefore, such adaptations and modifications are intended to be within the meaning and range of equivalents of the disclosed implementations, based on the teaching and guidance presented herein.

While the present disclosure contains many specific implementation details, these should not be construed as limitations on the scope of what is being claimed, which is defined by the claims themselves, but rather as descriptions of features that may be specific to particular implementations. Certain features that are described in this present disclosure in the context of separate implementations can also be implemented in combination in a single implementation. Conversely, various features that are described in the context of a single implementation can also be implemented in multiple implementations separately or in any suitable sub-combination. Moreover, although features may be described above as acting in certain combinations and even initially be claimed as such, one or more features from a claimed combination can in some cases be excised from the combination, and the claim may be directed to a sub-combination or variation of a sub-combination.

Similarly, while operations are depicted in the drawings and recited in the claims in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the implementations described above should not be understood as requiring such separation in all implementations, and it should be understood that the described program components and systems can generally be integrated together in a single software product or packaged into multiple software products.

Particular implementations of the subject matter have been described. Other implementations also are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing may be advantageous.

The breadth and scope of the present disclosure should not be limited by any of the above-described exemplary implementations, but should be defined only in accordance with the following claims and their equivalents.

What is claimed is:

1. A memory device, comprising:
a memory array comprising a plurality of memory banks; and
a control circuitry comprising:
a first regulator coupled to bit lines in a first memory bank of the plurality of memory banks; and
a second regulator coupled to the bit lines in the first memory bank, wherein an output of the first regulator is coupled to an output of the second regulator.

2. The memory device of claim 1, wherein the second regulator is closer to the first memory bank than the first regulator.

3. The memory device of claim 1, wherein the control circuitry further comprises:
a third regulator coupled to bit lines in a second memory bank of the plurality of memory banks, wherein the bit lines in the second memory bank are further coupled to the first regulator, wherein an output of the third regulator is coupled to the output of the first regulator.

4. The memory device of claim 1, wherein the control circuitry comprises:
a plurality of bank circuits corresponding to the plurality of memory banks; and
a peripheral circuit arranged to one side of the plurality of bank circuits,
wherein the second regulator is included in a first bank circuit corresponding to the first memory bank, and the first regulator is included in the peripheral circuit.

5. The memory device of claim 4, wherein each of the plurality of bank circuits comprises a corresponding second regulator coupled to bit lines in a corresponding memory bank of the plurality of memory banks.

6. The memory device of claim 4, wherein the first bank circuit further comprises:
one or more sense amplifiers coupled to the bit lines in the first memory bank; and
one or more word line drivers coupled to word lines in the first memory bank, and wherein the peripheral circuit further comprises:
an input/output circuit of the memory device.

7. The memory device of claim 4, wherein the second regulator is on an edge of the first bank circuit.

8. The memory device of claim 4, wherein a first output of the first regulator is coupled to a first output of the second regulator in the first bank circuit, and
wherein a second output of the first regulator is coupled to a second output of the second regulator in the first bank circuit.

9. The memory device of claim 8, wherein the bit lines in the first memory bank are numbered in sequence,
wherein the first output of the first regulator and the first output of the second regulator are coupled to odd-numbered bit lines of the bit lines in the first memory bank, and
wherein the second output of the first regulator and the second output of the second regulator are coupled to even-numbered bit lines of the bit lines in the first memory bank.

10. The memory device of claim 1, wherein the first regulator comprises one or more first operational amplifiers, one or more first transistors and one or more capacitors, and
wherein the second regulator comprises one or more second operational amplifiers and one or more second transistors.

11. The memory device of claim 10, wherein transistors included in the one or more second operational amplifiers are smaller in size than transistors included in the one or more first operational amplifiers.

12. The memory device of claim 1, wherein the first regulator is configured to operate while the first memory bank is in an inactive mode and while the first memory bank in an active mode, and
wherein the second regulator is configured to operate while the first memory bank is in the active mode, and to be disabled while the first memory bank is in the inactive mode.

13. The memory device of claim 12, wherein the second regulator is configured to be disabled by an internal switch in a corresponding second operational amplifier in the second regulator.

14. A memory device, comprising:
a first semiconductor structure comprising a memory array comprising a plurality of memory banks; and
a second semiconductor structure stacked with the first semiconductor structure, wherein the second semiconductor structure comprises a control circuitry comprising:
a plurality of bank circuits corresponding to the plurality of memory banks; and
a peripheral circuit arranged to one side of the plurality of bank circuits,
wherein the peripheral circuit comprises a first regulator coupled to bit lines in a first memory bank of the plurality of memory banks, and
wherein a first bank circuit corresponding to the first memory bank comprises a second regulator, wherein the second regulator is coupled to the bit lines in the first memory bank.

15. The memory device of claim 14, wherein the first semiconductor structure comprises first contact structures isolated by a first isolating material,
wherein the second semiconductor structure comprises second contact structures isolated by a second isolating material, and
wherein the first semiconductor structure and the second semiconductor structure are bonded together by the first contact structures being in contact with the second contact structures.

16. The memory device of claim 14, wherein the plurality of bank circuits are arranged in two rows,
wherein an output of the first regulator is coupled to outputs of second regulators in bank circuits in a first row, and
wherein the peripheral circuit further comprises an additional first regulator, wherein an output of the additional first regulator is coupled to outputs of second regulators in bank circuits in a second row.

17. The memory device of claim 14, wherein the control circuitry comprises:
a plurality of bank circuits corresponding to the plurality of memory banks; and
a peripheral circuit arranged to one side of the plurality of bank circuits,
wherein the second regulator is included in a first bank circuit corresponding to the first memory bank, and the first regulator is included in the peripheral circuit.

18. The memory device of claim 17, wherein each of the plurality of bank circuits comprises a corresponding second regulator coupled to bit lines in a corresponding memory bank of the plurality of memory banks.

19. The memory device of claim 17, wherein the second regulator is on an edge of the first bank circuit.

20. A memory system, comprising:
a memory device comprising:
a memory array comprising a plurality of memory banks; and
a control circuitry comprising:
a first regulator coupled to bit lines in a first memory bank of the plurality of memory banks; and
a second regulator coupled to the bit lines in the first memory bank, wherein an output of the first regulator is coupled to an output of the second regulator; and
a memory controller coupled to the memory device and configured to control the memory device.
